(19) United States
(12) Patent Application Publication
(10) Pub. No.: US 2023/0170192 A1
(43) Pub. Date: Jun. 1, 2023

(54) METHOD AND APPARATUS FOR REALTIME WAFER POTENTIAL MEASUREMENT IN A PLASMA PROCESSING CHAMBER

(71) Applicant: Applied Materials, Inc., Santa Clara, CA (US)

(72) Inventors: Yue GUO, Redwood City, CA (US); Kartik RAMASWAMY, San Jose, CA (US); Yang YANG, San Diego, CA (US)

(21) Appl. No.: 17/537,314

(22) Filed: Nov. 29, 2021

(51) Int. Cl. H01J 37/32; H01J 37/244; H01L 21/683; G01R 29/12

(52) U.S. Cl. CPC H01J 37/32935; H01J 37/32715; H01J 37/244; H01J 37/32697; H01L 21/6831; G01R 29/12

(57) ABSTRACT

Embodiments of the present disclosure generally include an apparatus and methods for measuring and controlling in real-time a potential formed on a substrate in a plasma processing chamber during plasma processing. Embodiments of the disclosure include a plasma processing system that includes a substrate support disposed within a processing volume of the plasma processing system, the substrate support comprising a substrate supporting surface and a dielectric layer disposed between a first electrode and the substrate supporting surface. The plasma processing system further includes a first generator coupled to a second electrode of the plasma processing system, and a sensor disposed a first distance from the substrate supporting surface. The first generator is configured to generate a plasma within the processing volume. The first electrode is disposed a second distance from the substrate supporting surface, and the first distance is less than the second distance. The sensor is generally configured to detect an electric field strength and/or a voltage formed on the substrate during plasma processing.

### BACKGROUND

### Field

Embodiments of the present disclosure generally relate to a system and methods used in semiconductor device manufacturing. More specifically, embodiments provided herein generally include an apparatus and methods for measuring and controlling a bias applied to a substrate during plasma processing.

### Description of the Related Art

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

A typical Reactive Ion Etch (RIE) plasma processing chamber includes a radio frequency (RF) bias generator, which supplies an RF voltage to a power electrode, such as a metal plate positioned adjacent to an “electrostatic chuck” (ESC) assembly, more commonly referred to as the “cathode”. The power electrode can be capacitively coupled to the plasma of a processing system through a thick layer of dielectric material (e.g., ceramic material), which is a part of the ESC assembly. In a capacitively coupled gas discharge, the plasma is created by using a radio frequency (RF) generator that is coupled to the power electrode, or a separate power electrode that is disposed outside of the ESC assembly and within the processing chamber, through an RF matching network (“RF match”) that tunes the apparent load to 500 to minimize the reflected power and maximize the power delivery efficiency. The application of RF voltage to the power electrode causes an electron-repelling plasma sheath to form over a processing surface of a substrate that is positioned on a substrate supporting surface of the ESC assembly during processing. The non-linear, diode-like nature of the plasma sheath results in rectification of the applied RF field, such that a direct-current (DC) voltage drop, or “self-bias”, appears between the substrate and the plasma, making the substrate potential negative with respect to the plasma potential. This voltage drop determines the average energy of the plasma ions accelerated towards the substrate, and thus etch anisotropically. More specifically, ion directionality, the feature profile, and etch selectivity to the mask and the stop-layer are controlled by the Ion Energy Distribution Function (IEDF). In plasmas with RF bias, the IEDF typically has two non-discrete peaks, one at a low energy and one at a high energy, and an ion population that has a range of energies that extend between the two peaks. The presence of the ion population in-between the two peaks of the IEDF is reflective of the fact that the voltage drop between the substrate and the plasma oscillates at the RF bias frequency. When a lower frequency RF bias generator is used to achieve higher self-bias voltages, the difference in energy between these two peaks can lead to process related issues, such as bowing of an etched feature walls formed on a surface of the substrate. Compared to the high-energy ions, the low-energy ions are less effective at reaching the corners at the bottom of the etched feature (e.g., due to the charging effect), but cause less sputtering of the mask material. This is important in high aspect ratio etch applications, such as hard-mask opening or dielectric mold etch. As feature sizes continue to diminish and the aspect ratio increases, while feature profile control requirements become more stringent, it becomes more desirable to have a well-controlled substrate bias and thus IEDF at the substrate surface during processing.

It has been found that conventional RF plasma-assisted etching processes, which only deliver sinusoidal waveform containing RF signals at conventional plasma generating biasing levels to one or more of the electrodes in a plasma processing chamber, do not adequately or desirably control the sheath properties and generated ion energies, which leads to undesirable plasma processing results. The undesirable processing results can include excessive sputtering of the mask layer and the generation of sidewall defects in high-aspect ratio features.

Moreover, substrate potential, or the self-bias created during plasma processing, is a critical parameter for assuring controllable and desirable plasma processing results. The determination of the substrate potential during plasma processing of a substrate can be used to improve the plasma processing results achieved on the substrate and subsequent substrates processed in the processing chamber. For example, the determination of the substrate potential in real time can be used to better control the actual bias voltage established at the substrate due to the capacitive coupling of a waveform applied to an adjacently positioned biasing electrode and compensate for any drift in the substrate potential due to changes in the processing environment. In other examples, the determination of the substrate potential can be used for plasma process diagnostics and optimization, and for electrostatic chucking and de-chucking control of the substrate during plasma processing. Conventionally, the potential of a substrate can only be inferred by use of an empirical model or experimentally measured by use of a wired non-production worthy dummy substrate or experimental probe using an offline non-production worthy diagnostic process testing method. Thus, using conventional processes, a direct real-time measurement substrate potential and real-time control of the substrate potential based on the measurement during the plasma processing of a semiconductor device containing production substrate is not possible.

Thus, there is a need in the art for plasma processing devices and biasing methods that are at least able to resolve the issues outlined above.

### SUMMARY

Embodiments of the disclosure include a plasma processing system that includes a substrate support disposed within a processing volume of the plasma processing system, the substrate support comprising a substrate supporting surface and a dielectric layer disposed between a first electrode and the substrate supporting surface. The plasma processing system further includes a first generator coupled to a second electrode of the plasma processing system, and a sensor disposed a first distance from the substrate supporting surface. The first generator is configured to generate a plasma within the processing volume. The first electrode is disposed a second distance from the substrate supporting surface, and the first distance is less than the second distance. The sensor is generally configured to detect an electric field strength and/or a voltage formed on the substrate during plasma processing.

Embodiments of the disclosure include a plasma processing system that includes a substrate support disposed within a processing volume of the plasma processing system, the substrate support comprising a substrate supporting surface, and a dielectric layer disposed between a first electrode and the substrate supporting surface. The plasma processing system also includes at least one sensor disposed a first distance from the substrate supporting surface, wherein the first electrode is disposed a second distance from the substrate supporting surface, the first distance and the second distance are measured in a first direction, the first distance is less than the second distance, and sensor is configured to detect an electric field strength or a voltage.

Embodiments of the disclosure include a plasma processing system that includes a substrate support disposed within a processing volume of the plasma processing system, the substrate support includes a substrate supporting surface, a first electrode disposed in the substrate support and a first distance from the substrate supporting surface, and a dielectric layer disposed between the substrate supporting surface and the first electrode. The plasma processing system also includes a pulsed voltage (PV) waveform generator coupled to the first electrode, a radio frequency (RF) waveform generator coupled to a second electrode of the plasma processing system, wherein the radio frequency (RF) waveform generator is configured to generate a plasma within the processing volume, and a sensor disposed a second distance from the substrate supporting surface. The first distance and the second distance can be measured in a first direction that is perpendicular to the substrate supporting surface. The second distance is less than the first distance, and the sensor is configured to detect either an electric field strength or a voltage.

Embodiments of the disclosure include a method for chucking a substrate, comprising generating a plasma in a processing region of a process chamber, applying a first voltage waveform to a first electrode disposed in a substrate support to capacitively couple the first voltage waveform to a substrate disposed on a substrate supporting surface of the substrate support, wherein the substrate support is disposed in the processing region, measuring a strength of an electric field or voltage formed between the first electrode and the substrate supporting surface using an electric field sensor, and altering the first voltage waveform based on the measured strength of the electric field or voltage.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a processing system, according to one or more embodiments, configured to practice the methods set forth herein.

FIG. 2 is a top isometric view of a substrate support assembly that is disposed in the processing system of FIG. 1, according to one or more embodiments.

FIG. 3A is a side cross-sectional view of the substrate support assembly as formed by sectioning the substrate support assembly of FIG. 2 along Section Line 3-3, according to one embodiment.

FIG. 3B illustrates a portion of the cross-sectional view of the substrate support assembly shown in FIG. 3A, according to an embodiment.

FIG. 4A illustrates a voltage waveform established on a substrate disposed on a substrate support assembly of a processing chamber, according to one or more embodiments.

FIG. 4B illustrates a pulsed voltage waveform applied to a bias electrode within the substrate support assembly of the processing chamber, according to one or more embodiments.

FIG. 5A is a schematic cross-sectional view of a substrate support assembly of the plasma processing system that includes a substrate potential sensing assembly, according to one embodiment.

FIG. 5B illustrates an example of a substrate potential sensing system that can be used in the substrate support assembly illustrated in FIG. 5A, according to one embodiment.

FIG. 6 is a schematic cross-sectional view of a substrate support assembly of the plasma processing system that includes another type of substrate potential sensing assembly, according to one embodiment.

FIG. 7 is a schematic cross-sectional view of a substrate support assembly of the plasma processing system that includes another type of substrate potential sensing assembly, according to one embodiment.

FIG. 8 is a schematic cross-sectional view of a substrate support assembly of the plasma processing system that includes another type of substrate potential sensing assembly, according to one embodiment.

FIG. 9 is a diagram illustrating a method for real-time wafer potential measurement in the plasma processing system, according to one embodiment.

FIG. 10 is a diagram illustrating a method for real-time wafer potential measurement in the plasma processing system, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a system used in semiconductor device manufacturing. More specifically, embodiments provided herein generally include apparatus and methods for measuring and controlling in real-time a potential formed on a substrate in a plasma processing chamber during plasma processing therein.

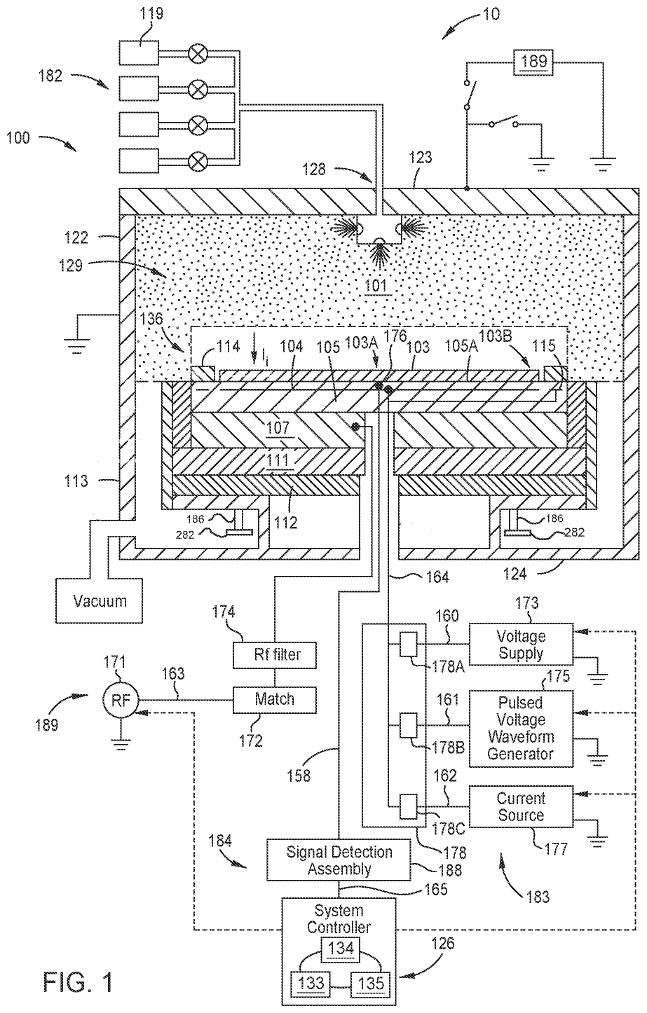

FIG. 1 is a schematic cross-sectional view of a plasma processing system 10 configured to perform one or more of the plasma processing methods set forth herein. In some embodiments, the plasma processing system 10 is configured for plasma-assisted etching processes, such as a reactive ion etch (RIE) plasma processing. The plasma processing system 10 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In one configuration, as shown in FIG. 1, the plasma processing system 10 is configured to form a capacitively coupled plasma (CCP). However, in some embodiments, a plasma may alternately be generated by an inductively coupled source disposed over the processing region of the plasma processing system 10. In this configuration, a coil may be placed on top of a ceramic lid (vacuum boundary) of the plasma processing system 10.

The plasma processing system 10 includes a processing chamber 100, a substrate support assembly 136, a gas system 182, a DC power system 183, an RF power system 189, a substrate potential sensing assembly 184, and a system controller 126. The processing chamber 100 includes a chamber body 113 that comprises a chamber lid 123, one or more sidewalls 122, and a chamber base 124. The chamber lid 123, one or more sidewalls 122, and the chamber base 124 collectively define the processing volume 129. The one or more sidewalls 122 and chamber base 124 generally include materials (such as aluminum, aluminum alloys, or stainless steel alloys) that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. A substrate 103 is loaded into, and removed from, the processing volume 129 through an opening (not shown) in one of the sidewalls 122. The opening is sealed with a slit valve (not shown) during plasma processing of the substrate 103. A gas system 182, which is coupled to the processing volume 129 of the processing chamber 100, includes a processing gas source 119 and a gas inlet 128 disposed through the chamber lid 123. The gas inlet 128 is configured to deliver one or more processing gases to the processing volume 129 from the plurality of processing gas sources 119.

The processing chamber 100 further includes an upper electrode (e.g., a chamber lid 123) and a lower electrode (e.g., a substrate support assembly 136) disposed in a processing volume 129. The upper electrode and lower electrode are positioned to face each other. As seen in FIG. 1, in one embodiment, a radio frequency (RF) source is electrically coupled to the lower electrode. The RF source is configured to deliver an RF signal to ignite and maintain a plasma (e.g., the plasma 101) between the upper and lower electrodes. In some alternative configurations, the RF source can also be electrically coupled to the upper electrode. For example, the RF source can be electrically coupled to the chamber lid. In another example, the RF source could also be electrically coupled to the support plate 107.

The substrate support assembly 136 includes a substrate support 105, a substrate support base 107, an insulator plate 111, a ground plate 112, a plurality of lift pins 186, one or more substrate potential sensing assemblies 184, and a bias electrode 104. Each of the lift pins 186 are disposed through a through hole 185 formed in the substrate support assembly 136 and are used to facilitate the transfer of a substrate 103 to and from a substrate support surface 105A of the substrate support 105. The substrate support 105 is formed of a dielectric material. The dielectric material can include a bulk sintered ceramic material, a corrosion-resistant metal oxide (for example, aluminum oxide (Al₂O₃), titanium oxide (TiO), yttrium oxide (Y₂O₃), a metal nitride material (for example, aluminum nitride (AlN), titanium nitride (TiN)), mixtures thereof, or combinations thereof.

The substrate support base 107 is formed of a conductive material (for example aluminum, an aluminum alloy, or a stainless steel alloy). The substrate support base 107 is electrically isolated from the chamber base 124 by the insulator plate 111, and the ground plate 112 interposed between the insulator plate 111 and the chamber base 124. In some embodiments, the substrate support base 107 is configured to regulate the temperature of both the substrate support 105, and the substrate 103 disposed on the substrate support 105 during substrate processing. In some embodiments, the substrate support base 107 includes one or more cooling channels (not shown) disposed therein that are fluidly coupled to, and in fluid communication with, a coolant source (not shown), such as a refrigerant source or substrate source having a relatively high electrical resistance. In other embodiments, the substrate support 105 includes a heater (not shown) to heat the substrate support 105 and substrate 103 disposed on the substrate support 105.

A bias electrode 104 is embedded in the dielectric material of the substrate support 105. Typically, the bias electrode 104 is formed of one or more electrically conductive parts. The electrically conductive parts typically include meshes, foils, plates, or combinations thereof. Here, the bias electrode 104 functions as a chucking pole (i.e., electrostatic chucking electrode) that is used to secure (e.g., electrostatically chuck) the substrate 103 to the substrate support surface 105A of the substrate support 105. In general, a parallel plate like structure is formed by the bias electrode 104 and a layer of the dielectric material that is disposed between the bias electrode 104 and the substrate supporting surface 105A. The dielectric material can typically have an effective capacitance CE of between about 5 nF and about 50 nF. Typically, the layer of dielectric material (e.g., aluminum nitride (AlN), aluminum oxide (Al₂O₃), etc.) has a thickness between about 0.05 mm and about 5 mm, such as between about 0.1 mm and about 3 mm, such as between about 0.1 mm and about 1 mm, or even between about 0.1 mm and 0.5 mm. The bias electrode 104 is electrically coupled to a clamping network, which provides a chucking voltage thereto. The clamping network includes a DC voltage supply 173 (e.g., a high voltage DC supply) that is coupled to a filter 178A of the filter 178 that is disposed between the DC voltage supply 173 and bias electrode 104. In one example, the filter 178A is a low-pass filter that is configured to block RF frequency and pulsed voltage (PV) waveform signals provided by other biasing components found within the processing chamber 100 from reaching the DC voltage supply 173 during plasma processing. In one configuration, the static DC voltage is between about −5000V and about 5000V, and is delivered using an electrical conductor (such as a coaxial power delivery line 160). In some embodiments, the bias electrode 104 can also bias the substrate 103 with respect to the plasma 101 using one or more of the pulsed-voltage biasing schemes described in further detail below.

In some configurations, the substrate support assembly 136, further includes an edge control electrode 115. The edge control electrode 115 is formed of one or more electrically conductive parts. The electrically conductive parts typically include meshes, foils, plates, or combinations thereof. The edge control electrode 115 is positioned below the edge ring 114 and surrounds the bias electrode 104 and/or is disposed a distance from a center of the bias electrode 104. In general, for a processing chamber 100 that is configured to process circular substrates, the edge control electrode 115 is annular in shape, is made from a conductive material, and is configured to surround at least a portion of the bias electrode 104. As seen in FIG. 1, the edge control electrode 115 is positioned within a region of the substrate support 105, and is biased by use of a pulsed voltage (PV) waveform generator 175. In one configuration, the edge control electrode 115 is biased by use of a PV waveform generator that is different from the PV waveform generator 175 used to bias electrode 104. In another configuration, the edge control electrode 115 is biased by splitting part of the signal provided from the PV waveform generator 175 to the bias electrode 104.

The DC power system 183 includes the DC voltage supply 173, the pulsed voltage (PV) waveform generator 175, and a current source 177. The RF power system 189 includes a radio frequency (RF) waveform generator 171, match 172, and a filter 174. As previously mentioned, the DC voltage supply 173 provides a constant chucking voltage, while the RF waveform generator 171 delivers an RF signal to the processing region, and the PV waveform generator 175 establishes a PV waveform at the bias electrode 104. Applying a sufficient amount of RF power to an electrode, such as the substrate support base 107, cause the plasma 101 to be formed in the processing region 129 of the processing chamber 100. In one configuration, the RF waveform has a frequency range between about 10 MHz and about 200 MHz.

In some embodiments, the power system 183 further includes a filter assembly 178 to electrically isolate one or more of the components contained within the power system 183. As shown in FIG. 1, a power delivery line 163 electrically connects the output of the RF waveform generator 171 to an impedance matching circuit 172, an RF filter 174 and substrate support base 107. Power delivery line 160 electrically connects the output of the voltage supply 173 to a filter assembly 178. Power delivery line 161 electrically connects the output of the PV waveform generator 175 to the filter assembly 178. Power delivery line 162 connects the output of the current source 177 to the filter assembly 178. In some embodiments, the current source 177 is selectively coupled to the bias electrode 104 by use of a switch (not shown) disposed in the delivery line 162, so as to allow the current source 177 to deliver a desired current to the bias electrode 104 during one or more stages (e.g., ion current stage) of the voltage waveform generated by the PV waveform generator 175. As seen in FIG. 1, the filter assembly 178, which can include multiple separate filtering components (i.e., discrete filters 178A-178C) that are each electrically coupled to the output node via power delivery line 164. The power delivery lines 160-164 include electrical conductors that include a combination of coaxial cables, such as a flexible coaxial cable that is connected in series with a rigid coaxial cable, an insulated high-voltage corona-resistant hookup wire, a bare wire, a metal rod, an electrical connector, of any combination of the above.

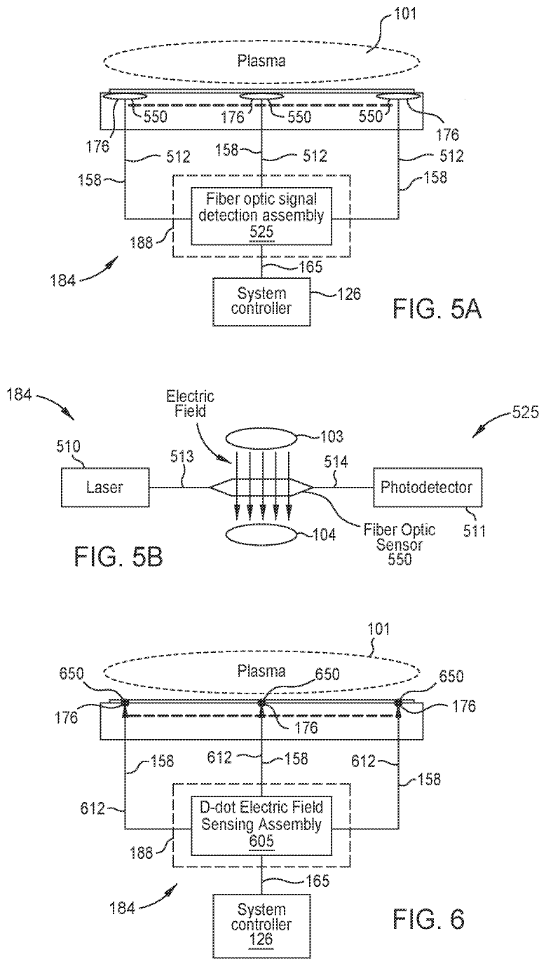

The substrate potential sensing assembly 184 includes one or more sensors 176 and a signal detection assembly 188. The substrate potential sensing assembly 184 is communicatively coupled to the system controller 126 via communication line 165. The signal detection assembly 188 generally includes components that are configured to receive a signal from a sensor 176 and form an output signal that can be used by the system controller 126. The system controller 126 can then use the received output signal to display a result or measurement performed by the sensor 176 and/or control some part of the processing chamber 100 or process performed therein. The one or more sensors 176 are coupled to the signal detection assembly 188 via the one or more communication lines 158. As explained further in FIGS. 5A, 6, 7 and 8, the one or more communication lines 158 includes a variety of different communication means, including a fiber optic cable, a coaxial cable and/or twisted pair cables.

The substrate potential sensing assembly 184 includes a signal detection assembly 188, and a sensor 176. As explained in further detail below, the signal detection assembly 188 includes multiple different embodiments, which all provide feedback to the system controller 126. Changes in a sensing parameter detected by a sensor 176 are transmitted to the signal detection assembly 188 using a sensing signal provided from the sensor 176. The signal detection assembly 188 receives the sensing signal, and then relays the signal to the system controller 126. The system controller 126 subsequently uses the input received from the substrate potential sensing assembly 184 to alter one or more plasma processing variables, such as altering a characteristic of a PV waveform generated by the PV waveform generator 175, and/or the amount of current provided from the current source 177 to the bias electrode 104.

The system controller 126, also referred to herein as a processing chamber controller, includes a central processing unit (CPU) 133, a memory 134, and support circuits 135. The system controller 126 is used to control the process sequence used to process the substrate 103. The CPU is a general-purpose computer processor configured for use in an industrial setting for controlling the processing chamber and sub-processors related thereto. The memory 134 described herein, which is generally non-volatile memory, can include random access memory, read-only memory, hard disk drive, or other suitable forms of digital storage, local or remote. The support circuits 135 are conventionally coupled to the CPU 133 and comprises cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the plasma processing system 10.

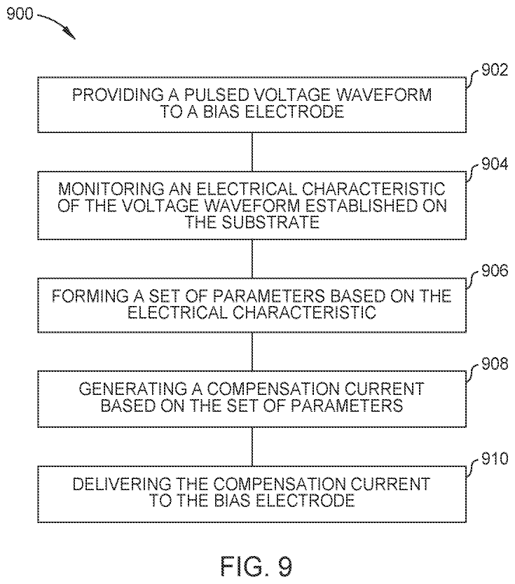

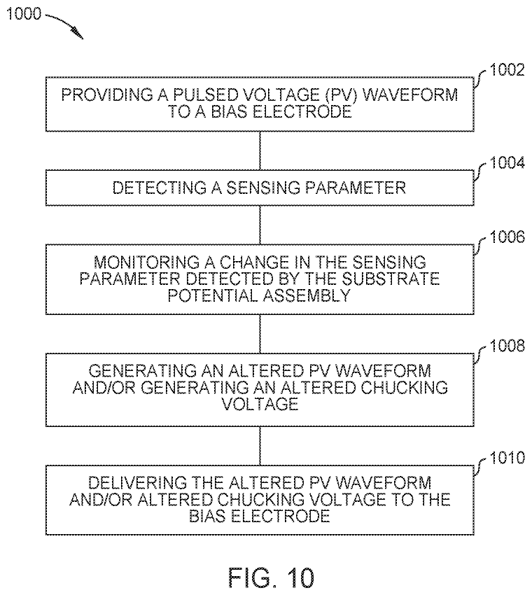

Typically, the program, which is readable by the CPU 133 in the system controller 126 includes code, which, when executed by the CPU 133, performs tasks relating to the plasma processing schemes described herein. The program may include instructions that are used to control the various hardware and electrical components within the plasma processing system 10 to perform the various process tasks and various process sequences used to implement the methods described herein. In one embodiment, the program includes instructions that are used to perform one or more of the operations described below in relation to FIGS. 9 and 10.

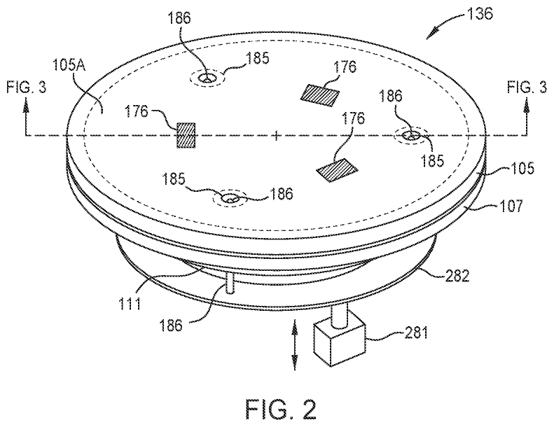

FIG. 2 is a top isometric view of the substrate support surface 105A of the substrate support 105 of the substrate support assembly 136. The substrate support assembly 136 can include the one or more sensors 176, a lift pin support structure 282 (i.e., lift pin hoop) for supporting the plurality of lift pins 186, and a lift pin actuator 281. Substrate support 105 includes a plurality of through holes 185, aligned with the plurality of lift pins 186, through which the plurality of lift pins 186 pass through. The lift pin hoop structure 282 is positioned beneath the substrate support assembly 136. During use, the plurality of lift pins 186 travel through the pin through-holes 185 in the substrate support 105 and substrate support base 107 to lift the substrate 103 off the substrate support surface 105A. Typically, the lift pins 186 lift the substrate 103 off the substrate support 105 to transfer the substrate to and from the processing chamber 100.

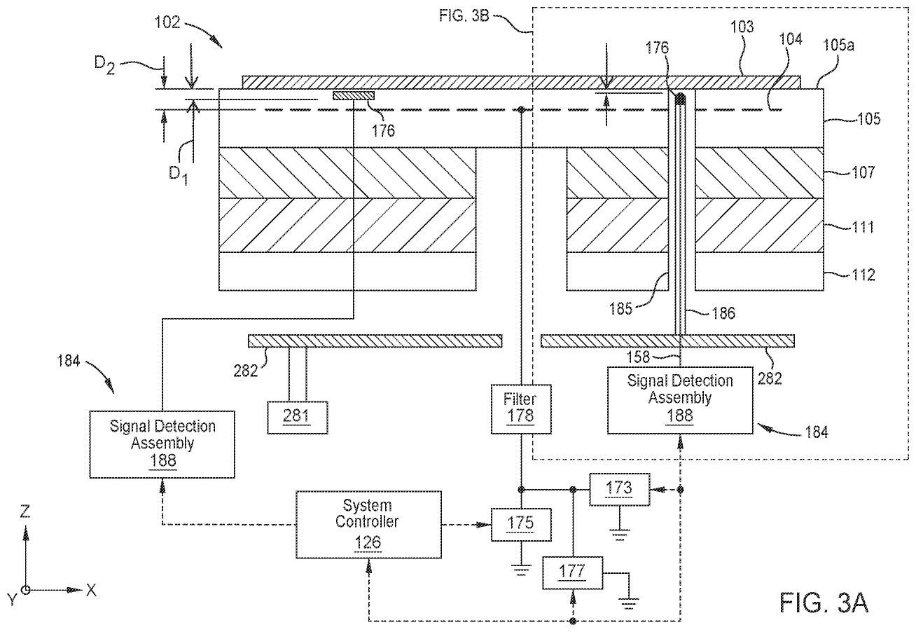

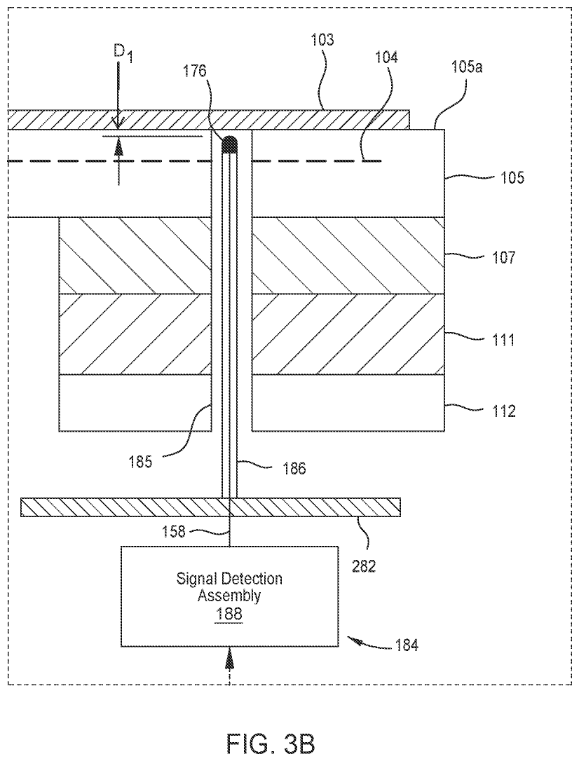

As seen in FIG. 2, the one or more sensors 176 are positioned to measure the potential of a substrate 103 that is disposed on the substrate support surface 105A during plasma processing. FIG. 3A is a side cross-sectional view of the substrate support assembly 136 as formed by sectioning the substrate support assembly 136 along Section Line 3-3 shown in FIG. 2, according to one embodiment. As seen in FIG. 3A, the signal detection assembly 188 of the substrate potential sensing assembly 184 is coupled to the one of the one or more sensors 176. In one embodiment, the one or more sensors 176 are disposed within the substrate support 105 and positioned on the same plane as the substrate support surface 105A. In another embodiment, the one or more sensors 176 are positioned a distance below the substrate support surface 105A, which can be measured in direction that is perpendicular to the substrate support surface 105A. The sensor 176 can generally be disposed a first distance D₁ from the substrate support surface 105A, where the first distance D₁ is between 0 mm and 5 mm from the substrate support surface 105A, such as less than 2 mm, or between 0.1 mm and 1 mm from the substrate support surface 105A, or even between 0.1 mm and 0.5 mm from the substrate support surface 105A. The bias electrode 104 is disposed a second distance D₂ from the substrate support surface 105A, such that, in some embodiments, the first distance D₁ is less than the second distance D₂. In some embodiments, the sensor 176 is disposed in the space between the bias electrode 104 and the substrate support surface 105A. In some applications, the sensor 176 is placed in the space between the bias electrode 104 and the top surface of the substrate support base 107. In some embodiments, there are multiple sensors that are disposed at different heights. For example, a first sensor is positioned between the bias electrode 104 and the substrate support surface 105A, and a second sensor is positioned between the bias electrode 104 and the top surface of the substrate support base 107.

FIG. 3B illustrates a portion of the cross-sectional view of the substrate support assembly 136 shown in FIG. 3A, according to an embodiment. As shown in FIG. 3B, the substrate potential sensing assembly 184 includes a sensor 176 that is positioned on a lift pin 186 to measure the substrate potential during plasma processing. As seen in FIG. 3B, sensor 176 is communicatively coupled to signal detection assembly 188 through the lift pin 186 via communication line 158, and is positioned on the substrate facing end of the lift pin 186 a first distance D₁ from the substrate supporting surface 105A during plasma processing. In some embodiments, the lift pins 186 are formed from a dielectric material or include an electrically isolated region (e.g., include a dielectric coating or insulation) that allows the electrical signals provided from the sensor 176 and along the communication line 158 to reach the signal detection assembly 188 without significant signal loss.

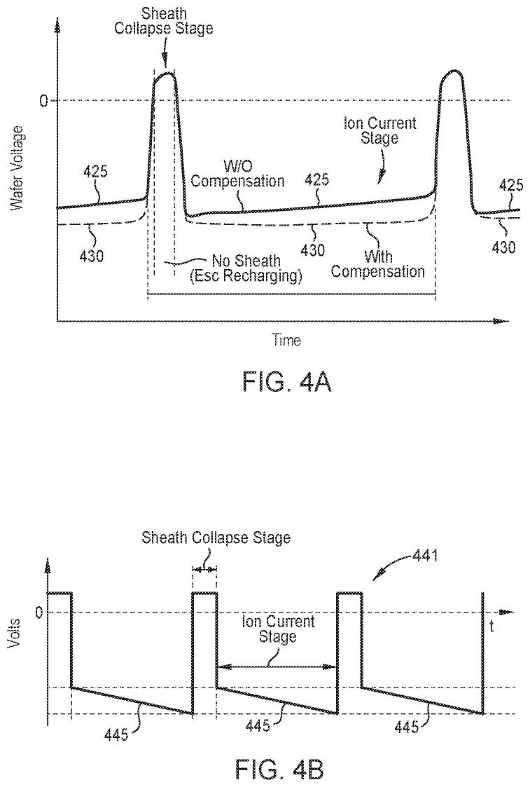

FIG. 4A illustrates an example of a voltage waveform that is established at a substrate 103 disposed on the substrate receiving surface 105A during plasma processing due to the delivery of a PV waveform to the biasing electrode 104, according to one or more embodiments. Waveform 425 is an example of a non-compensated waveform established at the substrate 103. Waveform 430 is an example of a compensated waveform established at the substrate. FIG. 4B illustrates an example of a pulsed voltage (PV) waveform applied to the bias electrode 104 of the processing chamber, according to one or more embodiments. In some embodiments, the waveform 441 includes a PV waveform that includes a first portion (e.g., ion current portion 445) that includes a negative slope (e.g., voltage per unit time) that is delivered to the electrode 104 during the ion current stage of the PV waveform to form a compensated waveform at the substrate, as will be further discussed below.

Waveforms 425, 430, and 441 generally include two main stages: an ion current stage and a sheath collapse stage. Both the ion current stage and the sheath collapse stage portions of the waveforms 425 and 430, which are established at the substrate 103, are shown in FIG. 4A. At the beginning of the ion current stage, a drop in voltage at the substrate 103 is created, due to the delivery of a negative portion of a PV waveform (e.g., ion current portion 445) provided to the bias electrode 104 by the PV waveform generator 175, which creates a high voltage sheath above the substrate 103. The high voltage sheath allows the plasma generated positive ions to be accelerated towards the biased substrate. As more positive ions bombard the surface of the substrate, an amount of positive charge builds up on the surface of the substrate 103 over time. The increase in positive charge on the substrate's surface gradually increases the voltage of the substrate, or “substrate potential.” As seen in FIG. 4A, waveform 425 gradually and undesirably increases from a more negative voltage at the beginning of the ion current stage to a less negative voltage during the latter portion of the ion current stage. If uncontrolled, the gradual accumulation of positive charge on the surface of the substrate results in the gradual discharge of the high voltage sheath and chuck capacitance, slowly decreasing the sheath voltage and bringing the substrate potential closer to zero. The voltage difference between the beginning and end of the ion current stage determines the width of an ion energy distribution function (IEDF). The greater the difference in voltage, the wider the IEDF width, which is undesirable for a number of reasons, as discussed above. To achieve monoenergetic ions and a narrower IEDF width, operations are performed to compensate for the changing substrate potential during the ion current stage, and create a substantially flat shaped region (e.g., near zero slope), such as illustrated by ion current stage portion of the waveform 430. To establish the substantially flat shaped region in the voltage waveform established at the substrate, a waveform 441 that includes a negative slope during the ion current stage (i.e., ion current portion 445 found in FIG. 4B) can be delivered to the bias electrode 104. Driving, and or implementing the negative voltage slope at the bias electrode 104 is also known as current compensation, which can be created by use of the current source 177 that is coupled to the bias electrode 104. The negative voltage slope implemented during ion current portion 445 is created by increasing the amount of electrons provided to the bias electrode 104 to cancel the otherwise increasing field caused by the accumulating positive charges due to the incoming ions. Therefore, by detecting the actual slope (dV/dt) of the voltage waveform established at the substrate 103, by use of the sensors 176 of the substrate potential sensing assembly 184, the system controller 126 can adjust the current provided by the current source 177 and/or alter the characteristics of the PV waveform generated by the PV waveform generator 175 to thereby maintain a constant sheath potential throughout the ion current stage of the waveform established at the substrate 103. In some embodiments, a DC supply current is used for implementing a ramp that has a desired slope during the ion current stage. One or more of the embodiments of the substrate potential sensing assembly 184 provided herein can thus be used to detect and compensate for the generated ion current (Iᵢₒₙ), which will vary as the plasma processing process parameters are varied (e.g., pulse waveform bias voltage, pressure, etc.).

FIG. 5A is a schematic cross-sectional view of a substrate support assembly of the plasma processing system that includes a substrate potential sensing assembly 184, according to one embodiment. As previously mentioned, the substrate potential sensing assembly 184 includes the signal detection assembly 188, and the one or more sensors 176. Here, the one or more sensors 176 include one or more fiber optic sensors 550, and the signal detection assembly 188 includes a fiber optic signal detection assembly 525 communicatively coupled to the one or more fiber optic sensors 550, via one or more optical fibers 512. As similarly discussed above in relation to the sensors 176 illustrated in FIGS. 2 and 3A-3B, the fiber optic sensors 550 may be distributed across the substrate supporting surface 105A and/or positioned on one or more lift pins 186. The fiber optic sensors 550 may also be positioned at a first distance D₁ from the substrate supporting surface 105A. The fiber optic signal detection assembly 525 is configured to receive a sensing signal from the fiber optic sensor 550, and then relay or condition and relay the signal to the system controller 126. The system controller 126 subsequently uses the input received from the fiber optic signal detection assembly 525 to alter one or more plasma processing variables, such as altering a characteristic of a PV waveform generated by the PV waveform generator 175, and/or the amount of current provided from the current source 177 to the bias electrode 104.

FIG. 5B illustrates an example of the fiber optic signal detection assembly 525. The fiber optic signal detection assembly 525 includes a laser 510 and a photodetector 511 that are optically coupled to the one or more the fiber optic sensors 550 (e.g., a crystal) by use of the optical fibers 512. The one or more optical fibers 512 include a first optical fiber 513, and a second optical fiber 514. The laser 510 is coupled to the fiber optic sensor 550 via the first fiber optic cable 513. The fiber optic sensor 550 is coupled to the photodetector 511 via the second fiber optic cable 514. The fiber optic sensor 550 is positioned between the substrate 103 and the bias electrode 104, such as the first distance D1. The fiber optic sensor 550 is configured to measure the electric field created between the substrate 103 and the bias electrode 104 during plasma processing.

The fiber optic sensor 550 includes an electro-optic (EO) effect sensing element (e.g., crystal) that is configured to detect a change in the electric field that passes there through, such as the electric field created between the substrate 103 and bias electrode 104 during plasma processing. In one embodiment, the electro-optic (EO) effect sensing element includes a crystal that uses Pockel's effect in which the birefringence of the crystal changes in proportion to the electric field applied to the optical crystal within the fiber optic sensor 550. Any change in the electric field will result in a change in a characteristic of light received by the photodetector 511, due to the effect the change in the electric field has on EO effect sensing element and the laser 510 generated light passing there through. Values associated with the change in the characteristic of the light received by the photodetector 511 can subsequently be relayed to the system controller 126 to determine the voltage formed on the substrate and whether the current compensation and/or pulse waveform parameters need to be adjusted. In some embodiments, advanced polymer optical sensor probes or slab coupled optical sensors can be used as the sensor probe.

FIG. 6 is a schematic cross-sectional view of a substrate support assembly of the plasma processing system that includes a substrate potential sensing assembly 184, according to one embodiment. As previously mentioned, the substrate potential sensing assembly 184 includes the signal detection assembly 188, and one or more sensors 176. Here, the signal detection assembly 188 includes a derivative (D-dot) electric field sensing assembly 605, and one or more sensors 176 include one or more D-dot sensors 650. As similarly discussed above in relation to the sensors 176 illustrated in FIGS. 2 and 3A-3B, the D-dot sensors 650 may be distributed across the substrate supporting surface 105A and/or positioned on one or more lift pins 186. The D-dot sensors 650 may also be positioned at a first distance D₁ from the substrate supporting surface 105A. The derivative (D-dot) electric field sensing assembly 605 is communicatively coupled to the one or more D-dot sensors 650 via communication line 612.

The D-dot sensors 650 are high frequency electric field sensors that measure the rate of change of electric-magnetic displacement over time. Typically, the D-dot sensor contains a dielectric material whose relative permittivity varies with the RF frequency. When immersed into a time changing electro-magnetic field experienced by the substrate 103 during plasma processing, the D-dot electric field sensors generate a small output voltage. Due to the position of the D-dot sensor 650 relative to the substrate 103, changes in a sensing parameter (e.g., electric field) detected by the D-dot sensor 650 are transmitted to the D-dot electric field sensing assembly 605. The D-dot electric field sensing assembly 605 receives the sensing signal, and relays, or conditions and relays, the signal to the system controller 126. The system controller 126 subsequently uses the input received from the D-dot electric field sensing assembly 605 to alter one or more plasma processing variables, such as altering a characteristic of a PV waveform generated by the PV waveform generator 175, and/or the amount of current provided from the current source 177 to the bias electrode 104.

FIG. 7 is a schematic cross-sectional view of a substrate support assembly of the plasma processing system that includes a substrate potential sensing assembly 184, according to one embodiment. As previously mentioned, the substrate potential sensing assembly 184 includes the signal detection assembly 188, and the sensor 176. Here, the signal detection assembly 188 includes a MOSFET device sensing assembly 740. The sensor 176 includes a MOSFET 720, a filter 710, and a probe 750. The probe 750 is communicatively coupled to the filter via communication line 705, and the MOSFET via communication line 703. The filter 710 prevents RF and/or pulsed voltage signals from negatively affecting the sensing function performed by the MOSFET 720.

The MOSFET 720 is a field-effect transistor that functions as a switch that is configured to toggle between in an open and closed state based on the amount of voltage received by the probe 750 that is coupled to the gate of the MOSFET 720. As similarly discussed above in relation to the sensors 176 illustrated in FIGS. 2 and 3A-3B, the one or more probes 750 can be distributed across the substrate supporting surface 105A and/or positioned on one or more lift pins 186 so as to detect and transmit the voltage of the substrate 103 to the gate of the MOSFET 720 during plasma processing. The probes 750 may also be positioned at a first distance D₁ from the substrate supporting surface 105A. The application of the voltage sensed by the probe 750 and applied to the gate will open or close the channel region of the MOSFET and thus control the current flowing between the source and drain due to a separate bias applied between the source and drain by a power source (not shown). A threshold voltage, which is applied via the communication line 703, is needed to turn the MOSFET device on, and thus the MOSFET 720 is configured to have a desired gate threshold voltage Vₜ based on a desired voltage that is to be detected by the probe 750. The threshold voltage is the minimum amount of gate-to-source voltage which must be applied to allow the conduction a charge through the channel of the MOSFET device. Changes in the sensing parameter (e.g., substrate voltage) detected by the MOSFET 720 are transformed into 1's and 0's, or “on” and “off” states of the MOSFET 720, that are detected by the MOSFET device sensing assembly 740. The “on” and “off” states of the MOSFET 720 are used to determine if the substrate voltage is greater than or less than a known value, and the MOSFET device sensing assembly 740 transmits the “on” and “off” state information to the system controller 126. The system controller 126 subsequently uses the input received from the MOSFET device sensing assembly 740 to alter one or more plasma processing variables, such as altering a characteristic of a PV waveform generated by the PV waveform generator 175, and/or the amount of current provided from the current source 177 to the bias electrode 104. In some embodiments, the substrate potential sensing assemblies 184 that include a MOSFET sensor 720 may further include a plurality of differently configured MOSFET devices 720 that are connected to a probe 750 and each of the MOSFET devices 720 are configured to have a different gate threshold voltage Vₜ so that different substrate voltage levels can be detected by the differently configured MOSFETs and used by the system controller 126 to control one or more of the plasma processing variables.

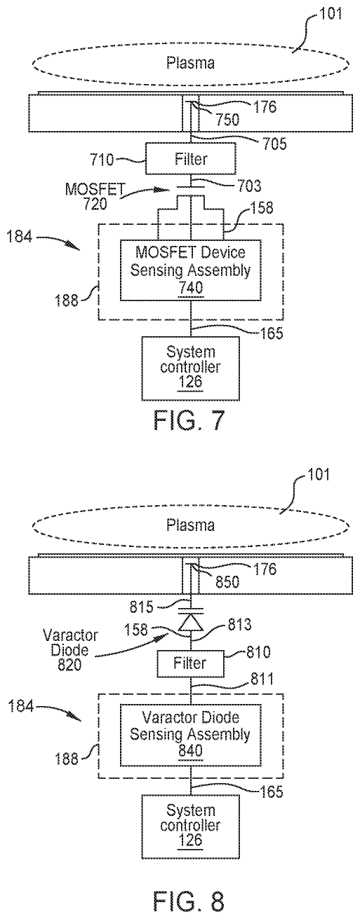

FIG. 8, is a schematic cross-sectional view of a substrate support assembly of the plasma processing system that includes a substrate potential sensing assembly 184, according to one embodiment. As previously mentioned, the substrate potential sensing assembly 184 includes the signal detection assembly 188, and the sensor 176. Here, the signal detection assembly 188 includes the varactor diode sensing assembly 840, and the sensor 176 includes a varactor diode 820 and a probe 850. As similarly discussed above in relation to the sensors 176 illustrated in FIGS. 2 and 3A-3B, the one or more probes 850 can be distributed across the substrate supporting surface 105A and/or positioned on one or more lift pins 186 so as to detect and transmit the voltage of the substrate 103 to the varactor diode 820 during plasma processing. The probes 850 may also be positioned at a first distance D₁ from the substrate supporting surface 105A. The probe 850 is communicatively coupled to the varactor diode 820 via communication line 815. The varactor diode 820 is communicatively coupled to a filter 810 via communication line 813. The filter 810 is communicatively coupled to the varactor diode sensing assembly 840 via communication line 811. The filter 810 prevents RF and/or pulsed voltage signals from negatively affecting the sensing function performed by the filter 810 prevents voltage back feeding from negatively affecting the varactor diode sensing assembly 840.

The varactor diode 820 is a voltage-dependent semiconductor device that has a varying internal capacitance based on an amount of a varying reverse bias voltage that is applied to the varactor diode 820 by communication line 815 that is coupled to the probe 850. When the reverse bias voltage is applied, the width of the depletion region in the diode portion of the varactor diode 820 increases and the capacitance decreases. Thus, increasing reverse bias voltage increases capacitance of the varactor diode 820 and decreasing reverse bias voltage decreases capacitance of the varactor diode 820. Changes in the sensing parameter (e.g., substrate voltage) detected by the varactor diode 820 is transmitted to the varactor diode sensing assembly 840. The varactor diode sensing assembly 840 receives the sensing signal provided by the varactor diode 820, and relays the signal to the system controller 126. The system controller 126 subsequently uses the input received from the varactor diode sensing assembly 840 to alter one or more plasma processing variables, such as altering a characteristic of a PV waveform generated by the PV waveform generator 175, and/or the amount of current provided from the current source 177 to the bias electrode 104.

### Processing Method Examples

FIG. 9 is a diagram illustrating a method for real-time wafer potential measurement of a substrate in a plasma processing chamber. The method 900 includes providing a voltage waveform to the bias electrode 104, monitoring an electrical characteristic of the voltage waveform established on a substrate 103, forming a set of parameters based on the electrical characteristic, generating a compensation current based on the set of parameters, and delivering the compensation current to the bias electrode 104 during a portion of the voltage waveform cycle.

At activity 902, the method 900 includes providing a voltage waveform to the bias electrode 104. The voltage waveform is generated by a waveform generator and provided via a communication line to the bias electrode 104. In some embodiments, the voltage waveform can be a pulsed voltage waveform that is similar to waveform 441 illustrated in FIG. 4B. The method further includes forming a plasma 101 in the processing chamber 100 at least partially due to the delivery of an RF signal, provided from the RF waveform generator 171 of the RF power system 189, to an electrode within the processing chamber 100.

At activity 904, the method 900 includes detecting a sensing parameter. In some embodiments, the sensing parameter includes one or more electrical characteristics of the substrate 103 such as the slope of the voltage and the magnitude of the voltage established at the substrate 103 in real time during plasma processing.

In one configuration, the one or more characteristics are measured using the substrate potential sensing assembly 184 of FIG. 5. In this example, the slope of the voltage waveform established at the substrate 103 during the ion current stage of the pulsed voltage waveform is detected by sensing the rate of change of the electric field formed between the substrate 103 and bias electrode 104, by use of one or more fiber optic sensors 550 that are disposed a first distance D₁ from the substrate support surface 105A. In another configuration, the one or more characteristics are measured using the substrate potential sensing assembly 184 of FIG. 6, which includes one or more D-dot electric field sensors 650 and the D-dot electric field sensing assembly 605. In yet another configuration, the one or more characteristics are measured using the substrate potential sensing assembly 184 of FIG. 7, which includes the MOSFET device sensing assembly and the MOSFET 720. In yet another configuration, the one or more characteristics are measured using the substrate potential sensing assembly 184 of FIG. 8, which includes the varactor diode sensing assembly 840 and the varactor diode 820.

At activity 906, the method 900 includes monitoring and analyzing a change in the sensing parameter detected by the substrate potential sensing assembly 184. Changes in the sensing parameter detected by the one or more sensors 176 are transmitted to the signal detection assembly 188 using a sensing signal provided from the one or more sensors 176. The signal detection assembly 188 receives the sensing signal, and relays the signal to the system controller 126. In some embodiments of the method 900, the system controller 126 compares the detected sensing parameter with information stored in memory of the system controller 126 to determine the desired amount of correction that is need to compensate for the plasma generated ion current during the ion current stage of the established pulsed waveform. The stored information may include equations or a look-up table that are configured to provide the amount of correction based on the current sensing parameter value relative to a desired sensing parameter value (e.g., amount of error). In one example, the sensing parameter is the change in electric field strength over time (i.e., slope), which is proportional to the change in substrate voltage over time, that is measured by use of a fiber optic sensor 550 and fiber optic signal detection assembly 525. The system controller 126 subsequently uses the change in voltage over time input received from the signal detection assembly 188 to generate and deliver a controlling signal to the current source 177 so that current source 177 will alter the amount of current provided to the bias electrode 104.

At activity 908, the method 900 includes generating a compensation current, by the current source 177, based on the analysis performed in activity 906 and the set of parameters provided within the controlling signal provided by system controller 126.

At activity 910, the method 900 includes delivering the compensation current to the bias electrode during the ion current stage of a voltage waveform, such as the voltage waveform illustrated in FIG. 4A. In one example, a negative voltage slope is established at the bias electrode 104 during the ion current stage of the pulsed waveform 441 to compensate for a detected change in the electric field sensed by the one or more fiber optic sensors 550 of the fiber optic signal detection assembly 525.

FIG. 10 is a diagram illustrating a method for real-time wafer potential measurement of a substrate in a plasma processing chamber. The method 1000 includes providing a pulsed voltage waveform, and a chucking voltage to a bias electrode, forming a sensing parameter, monitoring a change in the sensing parameter between the bias electrode and substrate, and altering the pulsed voltage waveform, and/or chucking voltage based on the change in the sensing parameter.

At activity 1002, the method 1000 includes providing a voltage waveform to the bias electrode 104. The voltage waveform is generated by a waveform generator and provided via a communication line to the bias electrode 104. In some embodiments, the voltage waveform can be a pulsed voltage waveform that is similar to waveform 441 illustrated in FIG. 4B. The method 1000 further includes forming a plasma 101 in the processing chamber 100 at least partially due to the delivery of an RF signal, provided from the RF waveform generator 171 of the RF power system 189, to an electrode within the processing chamber 100.

At activity 1004, the method 1000 includes detecting a sensing parameter. In some embodiments, the sensing parameter includes one or more electrical characteristics of the substrate 103 such as the slope of the voltage or the magnitude of the voltage established at the substrate 103 in real time during plasma processing.

In one configuration, the one or more characteristics are measured using the substrate potential sensing assembly 184 of FIG. 5, which includes one or more fiber optic sensors 550 and the fiber optic signal detection assembly 525. In another configuration, the one or more characteristics are measured using the substrate potential sensing assembly 184 of FIG. 6, which includes one or more D-dot electric field sensors 650, and the D-dot electric field sensing assembly 605. In another configuration, the one or more characteristics are measured using the substrate potential sensing assembly 184 of FIG. 7, which includes the MOSFET device sensing assembly, and the MOSFET 720. In yet another configuration, the one or more characteristics are measured using the substrate potential sensing assembly 184 of FIG. 8, which includes the varactor diode sensing assembly 840, and the varactor diode 820.

At activity 1006, the method 1000 includes monitoring and analyzing a change in the sensing parameter detected by the substrate potential sensing assembly 184. In some embodiments, the sensor 176 of the substrate potential sensing assembly 184 is disposed between the bias electrode 104 and the substrate 103. Changes in the sensing parameter detected by the one or more sensors 176 are transmitted to the signal detection assembly 188 using a sensing signal provided from the one or more sensors 176. The signal detection assembly 188 receives the sensing signal, and relays or conditions and relays the signal to the system controller 126. In some embodiments of the method 900, the system controller 126 compares the detected sensing parameter with information stored in memory of the system controller 126 to determine the desired amount of correction. The stored information may include equations or a look-up table that are configured to provide the amount of correction based on the current sensing parameter value related to a desired sensing parameter value (e.g., amount of error). In one example, the sensing parameter is the magnitude of the substrate voltage at any instant in time. The system controller 126 subsequently uses the detected voltage received from the signal detection assembly 188 to generate and deliver a controlling signal to the PV waveform generator 175 and/or the voltage supply 173, so that the PV waveform generator 175 and/or voltage supply 173 will alter the voltage provided to the bias electrode 104 and/or an edge control electrode 115. In one example, the PV waveform generator 175 will alter the PV waveform provided to the bias electrode based on the detected magnitude of the voltage established at the substrate 103 at that instant in time. Thus, the substrate potential sensing assembly 184 and system controller can be used to compensate for a drift in the pulsed waveform voltage, which was detected by the substrate potential sensing assembly 184. In another example, the voltage supply 173 alters the chucking voltage provided to the bias electrode 104 based on the delivery of the controlling signal from the system controller 126 that is based on the detected magnitude of the voltage established at the substrate 103.

At activity 1008, the method 1000 includes generating an altered PV waveform by the PV waveform generator 175, and/or generating an altered chucking voltage that is applied to the bias electrode 104 and/or an edge control electrode 115 by at least one voltage supply 173. In some embodiments, the altered chucking voltage applied to the bias electrode 104 and/or edge control electrode is generated by more than one voltage supplies. In one example, generating an altered chucking voltage includes altering a pulsed voltage waveform applied to the bias electrode 104 by applying a DC bias voltage to the bias electrode 104 using the voltage supply 173. The applied DC bias voltage is provided such that the applied DC bias voltage alters the DC voltage level of the voltage waveform applied by the PV waveform generator 175, and thus alters an electrostatic chucking force applied to the substrate. In one embodiment, the electrostatic chucking force can be measured to determine when the substrate is fully discharged during a dechucking process. In some cases, the voltage at either the substrate and/or the bias electrode can be measured to determine if and/or when the substrate is fully discharged during a dechucking process. Once the residual charge is discharged, lift pins can move up safely to prevent substrate breakage due to residual electrostatic forces resisting the ability of the lift pins to lift the substrate from the substrate supporting surface.

At activity 1010, the method 1000 includes delivering the altered PV waveform and/or altered chucking voltage to the bias electrode 104 during the one or more stages of the voltage waveform of FIG. 4A.

While the forgoing is directed to embodiments of the present disclosure, other and further embodiments of the disclosure may be devised without departing from the basic scope thereof, and the scope thereof is determined by the claims that follow.

What is claimed is:

1. A plasma processing system, comprising:
a substrate support disposed within a processing volume of the plasma processing system, the substrate support comprising:
a substrate supporting surface; and
a dielectric layer disposed between a first electrode and the substrate supporting surface; and
at least one sensor disposed a first distance from the substrate supporting surface, wherein
the first electrode is disposed a second distance from the substrate supporting surface;
the first distance and the second distance are measured in a first direction;
the first distance is less than the second distance; and
the sensor is configured to detect an electric field strength or a voltage.

2. The plasma processing system of claim 1, further comprising a first generator coupled to a second electrode of the plasma processing system, wherein the first generator is configured to generate a plasma within the processing volume.

3. The plasma processing system of claim 2, further comprising:
a pulse voltage (PV) waveform generator coupled to the first electrode;
a direct current (DC) voltage supply coupled to the first electrode;
a current source that is selectively coupled to the first electrode;
one or more filters disposed between the pulse waveform generator and the first electrode; and
one or more filters disposed between the voltage supply and the first electrode,
wherein the first generator comprises a radio frequency (RF) waveform generator.

4. The plasma processing system of claim 1, wherein the sensor comprises a fiber optic electric field sensor that is configured to detect an electric field strength.

5. The plasma processing system of claim 1, wherein the sensor comprises an electric field derivative sensor that is configured to detect an electric field strength.

6. The plasma processing system of claim 1, wherein the sensor comprises a MOSFET device.

7. The plasma processing system of claim 1, wherein the sensor comprises a varactor diode.

8. The plasma processing system of claim 1, wherein the first electrode is an electrostatic chucking electrode.

9. The plasma processing system of claim 1, wherein the second distance is less than or equal to 5 mm.

10. The plasma processing system of claim 1, further comprising a controller having a processor configured to execute computer-readable instructions that cause the system to:
apply, by use of a pulsed voltage (PV) waveform generator, a first voltage waveform to the first electrode,
measure a strength of the electric field over time using the sensor; and
alter a pulse voltage (PV) waveform generated by the pulse voltage (PV) waveform generator or alter a current applied to the first electrode by a current source that is electrically coupled to the first electrode.

11. A plasma processing system, comprising:
a substrate support disposed within a processing volume of the plasma processing system, the substrate support comprising:
a substrate supporting surface;
a first electrode disposed in the substrate support and a first distance from the substrate supporting surface; and
a dielectric layer disposed between the substrate supporting surface and the first electrode;
a pulsed voltage (PV) waveform generator coupled to the first electrode;
a radio frequency (RF) waveform generator coupled to a second electrode of the plasma processing system, wherein the radio frequency (RF) waveform generator is configured to generate a plasma within the processing volume; and
a sensor disposed a second distance from the substrate supporting surface, wherein
the first distance and the second distance are measured in a first direction;
the second distance is less than the first distance; and
the sensor is configured to detect either an electric field strength or a voltage.

12. The plasma processing system of claim 11, further comprising:
a DC voltage source coupled to the first electrode; and
one or more filters to electrically isolate a DC voltage waveform from a PV waveform.

13. The plasma processing system of claim 11, wherein the sensor comprises a fiber optic electric field sensor.

14. The plasma processing system of claim 11, wherein the sensor comprises an electric field derivative sensor.

15. The plasma processing system of claim 11, wherein the sensor comprises a MOSFET device.

16. The plasma processing system of claim 11, wherein the sensor comprises a varactor diode.

17. The plasma processing system of claim 11, further comprising a controller having a processor configured to execute computer-readable instructions that cause the system to:
apply a first voltage waveform to the first electrode by use of a pulsed voltage (PV) waveform generator,
measure the strength of the electric field over time using the sensor; and
alter a pulse voltage (PV) waveform generated by the pulse voltage (PV) waveform generator or alter a current applied to the first electrode by a current source that is electrically coupled to the first electrode.

18. A method for chucking a substrate, comprising:
generating a plasma in a processing region of a process chamber;
applying a first voltage waveform to a first electrode disposed in a substrate support to capacitively couple the first voltage waveform to a substrate disposed on a substrate supporting surface of the substrate support, wherein the substrate support is disposed in the processing region;
measuring a strength of an electric field formed between the first electrode and the substrate supporting surface using an electric field sensor; and
altering the first voltage waveform based on the measured strength of the electric field.

19. The method of claim 18, wherein generating the plasma comprises delivering a radio frequency (RF) waveform to one or more second electrodes.

20. The method of claim 19, wherein altering the first voltage waveform comprises applying a DC bias voltage to the first electrode, wherein the DC bias voltage is configured to alter an electrostatic chucking force applied to the substrate.
